(19) United States
(12) Patent Application Publication
(10) Pub. No.: US 2024/0044990 A1
(43) Pub. Date: Feb. 8, 2024

(54) SEMICONDUCTOR DEVICE, BATTERY PACK, METHOD OF CONTROLLING SEMICONDUCTOR DEVICE, AND CONTROL PROGRAMS

(71) Applicant: Renesas Electronics Corporation, Tokyo (JP)

(72) Inventor: Gen NAGASHIMA, Tokyo (JP)

(73) Assignee: Renesas Electronics Corporation, Tokyo (JP)

(21) Appl. No.: 18/359,068

(22) Filed: Jul. 26, 2023

(30) Foreign Application Priority Data
Aug. 3, 2022 (JP) 2022-123755

(51) Int. Cl. G01R 31/3828; H02J 7/00

(52) U.S. Cl. CPC G01R 31/3828; H02J 7/0048; H02J 7/0013; H02J 7/0029

(57) ABSTRACT

A semiconductor device, a battery pack, a method of controlling the semiconductor device, and a control program capable of accurately measuring a remaining capacity of a battery is provided. The semiconductor device includes: a current measurement circuit configured to measure a current value of a first current supplied from a battery to the semiconductor device that is a host device and a current value of a second current supplied from the battery to a load; and a computing circuit configured to calculate the remaining capacity of the battery, based on an accumulation value of the first current and an accumulation value of the second current in a period from start of discharging to end of discharging in the battery.

### CROSS-REFERENCE TO RELATED APPLICATION

The subject application claims priority under 35 U.S.C. § 119 to Japanese Patent Application No. 2022-123755, filed on Aug. 3, 2022. The disclosure of Japanese Patent Application No. 2022-123755, including the specification, drawings and abstract is incorporated herein by reference in its entirety.

### BACKGROUND

The present disclosure relates to semiconductor devices, battery packs, methods of controlling semiconductor devices, and control programs, and relates to, for example, a semiconductor device, a battery pack, a method of controlling a semiconductor device, and control programs suitable for accurately measuring a remaining capacity of a battery.

There is disclosed technique listed below.

[Patent Document 1] Japanese Patent No. 6298616

A battery pack to be connected to a load such as a notebook computer or smartphone is configured of a battery for supplying power to the load and a battery management device for management of the battery. A technique regarding a battery pack is disclosed in, for example, the Patent Document 1.

### SUMMARY

Meanwhile, a battery management device has a function of calculating the remaining capacity of the battery. The remaining capacity of the battery is calculated by subtracting the use capacity of the battery (capacity discharged from the battery in a period from start of discharging to end of discharging in the battery) from the full-charge capacity of the battery (capacity discharged from the battery in a period from a full charging state to complete discharging in the battery). Thus, the battery management device is desired to accurately measure the remaining capacity of the battery by accurately measuring the full-charge capacity of the battery.

Here, before advancement of low power consumption of the load, a consumed current of the battery management device was negligibly small in comparison with a consumed current of the load, and was thus not considered in measurement of the full-charge capacity of the battery. However, in recent years, with the advancement of the low power consumption of the load, increase of the consumed current of the battery management device has not become negligible in comparison with the consumed current of the load. Thus, in consideration of only the consumed current of the load, the battery management device cannot accurately measure the full-charge capacity of the battery. As a result, there is a problem of failure to accurately measure the remaining capacity of the battery. Other problems and novel characteristics will become apparent from the description of the specification and the attached drawings.

A semiconductor device according to the present disclosure includes: a current measurement circuit configured to measure a current value of a first current supplied from a battery to the semiconductor device that is a host device and a current value of a second current supplied from the battery to a load; and a computing circuit configured to calculate a remaining capacity of the battery, based on an accumulation value of the first current and an accumulation value of the second current in a period from start of discharging to end of discharging in the battery.

A method of controlling a semiconductor device according to the present disclosure includes: a step of measuring a current value of a first current supplied from a battery to the semiconductor device that is a host device and a current value of a second current supplied from the battery to a load; and a step of calculating a remaining capacity of the battery, based on an accumulation value of the first current and an accumulation value of the second current in a period from start of discharging to end of discharging in the battery.

A control program according to the present disclosure causes a computer to perform a process of measuring a current value of a first current supplied from a battery to a semiconductor device that is a host device and a current value of a second current supplied from the battery to a load and a process of calculating a remaining capacity of the battery, based on an accumulation value of the first current and an accumulation value of the second current in a period from start of discharging to end of discharging in the battery.

The present disclosure can provide a semiconductor device, a battery pack, a method of controlling a semiconductor device, and control programs capable of accurately measuring a remaining capacity of a battery.

### BRIEF DESCRIPTIONS OF THE DRAWINGS

FIG. 1 is a block diagram depicting a configurational example of a battery pack including a battery management device according to a first embodiment.

FIG. 2 is a block diagram depicting a configurational example of a basic portion of the battery management device provided to the battery pack shown in FIG. 1.

FIG. 3 is a diagram depicting a configurational example of a part of the battery management device according to the first embodiment.

FIG. 4 is a flowchart depicting operation of the battery management device according to the first embodiment.

FIG. 5 is a block line diagram for describing operation of a computing circuit provided to the battery management device according to the first embodiment.

FIG. 6 is a diagram depicting a first modification example of the battery management device according to the first embodiment.

FIG. 7 is a diagram depicting a second modification example of the battery management device according to the first embodiment.

FIG. 8 is a flowchart depicting operation of measuring a current self-consumed by the battery management device shown in FIG. 7.

FIG. 9 is a diagram depicting a third modification example of the battery management device according to the first embodiment.

FIG. 10 is a diagram for describing operation mode of the battery management device shown in FIG. 9.

FIG. 11 is a diagram depicting a state of the battery management device shown in FIG. 9 in load non-connection mode.

FIG. 12 is a diagram depicting a state of the battery management device shown in FIG. 9 in heavy-load connection mode.

FIG. 13 is a diagram depicting a state of the battery management device shown in FIG. 9 in light-load connection mode.

FIG. 14 is a timing chart depicting one example of operation of the battery management device shown in FIG. 9 in light-load connection mode.

FIG. 15 is a timing chart depicting another example of operation of the battery management device shown in FIG. 9 in light-load connection mode.

FIG. 16 is a timing chart depicting still another example of operation of the battery management device shown in FIG. 9 in light-load connection mode.

FIG. 17 is a flowchart depicting operation of the battery management device shown in FIG. 9 in light-load connection mode.

FIG. 18 is a diagram depicting a fourth modification example of the battery management device according to the first embodiment.

FIG. 19 is a diagram depicting a fifth modification example of the battery management device according to the first embodiment.

FIG. 20 is a diagram depicting a configurational example of a part of a battery management device according to a second embodiment.

FIG. 21 is a diagram depicting a configurational example of a part of a battery management device according to a third embodiment.

FIG. 22 is a diagram depicting a modification example of the battery management device according to the third embodiment.

FIG. 23 is a diagram depicting a configurational example of a part of a battery management device according to a fourth embodiment.

### DETAILED DESCRIPTION

Embodiments will be described below with reference to the drawings. Note that the drawings are simplified, and therefore, the technical scope of the embodiments should not be interpreted to be narrowed based on the illustration of these drawings. Also, the same component is denoted by the same reference sign, and the repetitive description thereof is omitted.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, an application example, detailed explanation, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the number of elements (including number of pieces, values, amount, range, and the like).

### First Embodiment

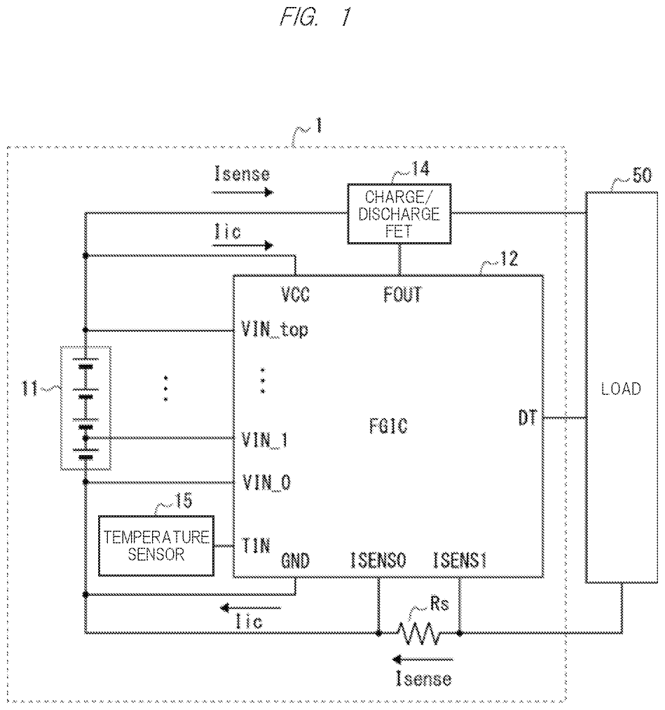

FIG. 1 is a block diagram depicting a configurational example of a battery pack 1 including a battery management device 12 according to a first embodiment. Note that FIG. 1 also depicts a load 50 connected to the battery pack 1. The load 50 is, for example, a notebook computer, smartphone, or the like.

As shown in FIG. 1, the battery pack 1 includes a battery 11 for supplying power to the load, a battery management device (semiconductor device) 12 for management of the battery 11, a resistance element (second resistance element) Rs, a charge/discharge FET 14, and a temperature sensor 15.

The battery 11 is, for example, a lithium-ion-type battery, and is configured of “m” battery cells (“m” is an integer equal to or larger than 1) connected in series.

The charge/discharge FET 14 is provided on a current path connecting the battery 11 and the load 50. The charge/discharge FET 14 interrupts charge/discharge current flowing through the current path when an anomaly is detected in current flowing between the battery 11 and the load 50 by the battery management device 12.

The temperature sensor 15 is provided near the battery 11 to detect a temperature of the battery 11. More specifically, the temperature sensor 15 has a thermistor in which a resistance value varies depending on a temperature, and outputs a potential difference between both ends of the thermistor. By extracting a temperature corresponding to this potential difference from a temperature resistance characteristic table or the like, a temperature of the periphery (that is the battery 11) of the temperature sensor 15 is provided.

A resistance element Rs is provided on the current path connecting the battery 11 and the load 50. Therefore, through the resistance element Rs, current supplied from the battery 11 to the load 50 flows.

The battery management device 12 is also called an FGIC (Fuel Gauge Integrated Circuit), measuring the remaining amount of the battery 11 and protecting the battery 11 from overvoltage and overcurrent.

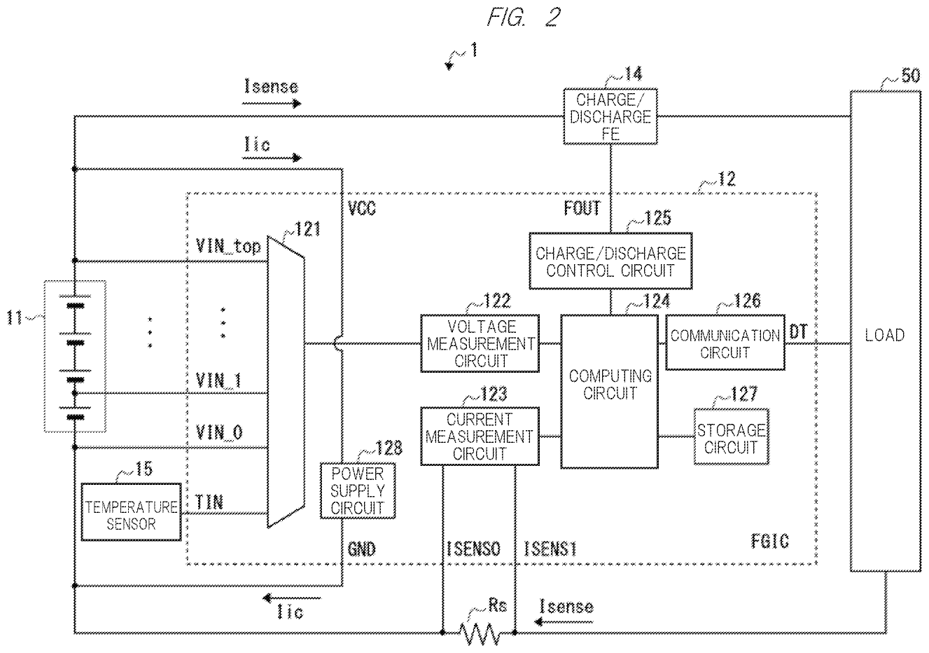

FIG. 2 is a block diagram depicting a configurational example of a basic portion of the battery management device 12. As shown in FIG. 2, the battery management device 12 includes at least a selector 121, a voltage measurement circuit 122, a current measurement circuit 123, a computing circuit 124, a charge/discharge control circuit 125, a communication circuit 126, a storage circuit 127, and a power supply circuit 128.

Note that the battery management device 12 is provided with at least external terminals VCC, GND, VIN_0 to VIN_m-1, VIN_top, TIN, ISENS0, ISENS1, FOUT, and DT. To the external terminal VCC, output voltage of the battery 11 (voltage of a positive-electrode-side terminal of the battery 11) is suppled from outside the battery management device 12. To the external terminal GND, reference voltage of the battery 11 (voltage of a negative-electrode-side terminal of the battery 11) is supplied from outside the battery management device 12. In the present embodiment, a case of 0 V as the reference voltage of the battery 11 will be explained as an example. To the external terminal VIN_0, voltage of the negative-electrode-side terminal of the battery 11 is supplied from outside the battery management device 12. To the respective external terminals VIN_1 to VIN_m-1, voltage of nodes between m battery cells configuring the battery 11 are supplied from outside the battery management device 12. To the external terminal VIN-top, voltage of the positive-electrode-side terminal of the battery 11 is supplied from outside the battery management device 12. To the external terminal TIN, output voltage of the temperature sensor 15 (voltage in accordance with the temperature detected by the temperature sensor 15 is supplied from outside the battery management device 12. To the external terminals ISENS0 and ISENS1, voltage between both ends of the resistance element Rs is supplied from outside the battery management device 12. The battery management device 12 outputs a control signal via the external terminal FOUT toward the charge/discharge FET 14. Also, the battery management device 12 transmits and receives data to and from the load 50 via the external terminal DT.

The selector 121 selects and outputs at least any of voltages of the positive-electrode-side terminal and the negative-electrode-side terminal of the battery 11, voltage of the respective nodes between the m battery cells configuring the battery 11, and output voltage of the temperature sensor 15, based on the computation result made by the computing circuit 124 and so forth. For example, the selector 121 can also select and output a potential difference between the positive-electrode-side terminal and the negative-electrode-side terminal of the battery 11 (that is, voltage of each of the positive-electrode-side terminal and the negative-electrode-side terminal of the battery 11).

The voltage measurement circuit 122 measures voltage selected by the selector 121. Note that when a potential difference between the positive-electrode-side terminal and the negative-electrode-side terminal of the battery 11 is selected by the selector 121, the voltage measurement circuit 122 measures the potential difference between the positive-electrode-side terminal and the negative-electrode-side terminal of the battery 11. The potential difference between the positive-electrode-side terminal and the negative-electrode-side terminal of the battery 11 corresponds to output voltage of the battery 11.

The current measurement circuit 123 measures a current value Isense of a current (second current) flowing through the resistance element Rs. In other words, the current measurement circuit 123 measures the current value Isense of the current supplied from the battery 11 to the load 50. For example, the current measurement circuit 123 has an AD converter which detects a potential difference between both ends of the resistance element Rs, and calculates the current value Isense of the current flowing through the resistance element Rs based on a resistance value of the resistance element Rs and the potential difference between both ends of the resistance element Rs detected by the AD converter.

The computing circuit 124 executes a predetermined computing process to the result of measurement made by the voltage measurement circuit 122, the result of measurement made by the current measurement circuit 123, a result of measurement made by a current measurement circuit 129 described later, and so forth, and then, the computing circuit 124 instructs each functional block of the battery management device 12 to perform a predetermined operation, based on the result of the computing process. For example, the computing circuit 124 instructs the communication circuit 126 to transmit data obtained by the process performed by the computing circuit 124 to the load 50 or to receive data transmitted from the load 50. Also, when an anomaly is detected in the current flowing between the battery 11 and the load 50, the computing circuit 124 instructs the charge/discharge control circuit 125 to interrupt the charge/discharge current flowing through the current path.

In the storage circuit 127, the result of the computing process performed by the computing circuit 124, intermediate data generated in the course of the computing, and so forth are stored. Also, the storage circuit 127 has stored therein information about the charge rate of the battery in accordance with the output voltage of the battery 11 (potential difference between both ends of the battery 11). For example, the storage circuit 127 has stored therein information indicating that the charge rate of the battery 11 is 100% when the output voltage of the battery 11 is the maximum value and information indicating that the charge rate of the battery 11 is 0% when the output voltage of the battery 11 is the minimum value.

The power supply circuit 128 is provided between the external terminals VCC and GND, and generates operating voltage of each internal circuit (each functional block) of the battery management device 12. In other words, the power supply circuit 128 converts the output voltage of the battery 11 to voltage suitable for operation of the internal circuit of the battery management device 12, and outputs the converted voltage. The internal circuit of the battery management device 12 is driven by voltage generated by the power supply circuit 128.

Here, the battery management device 12 further includes the current measurement circuit 129 (not shown in FIG. 2) which measures a current value Iic of current (first current) supplied from the battery 11 to the battery management device 12.

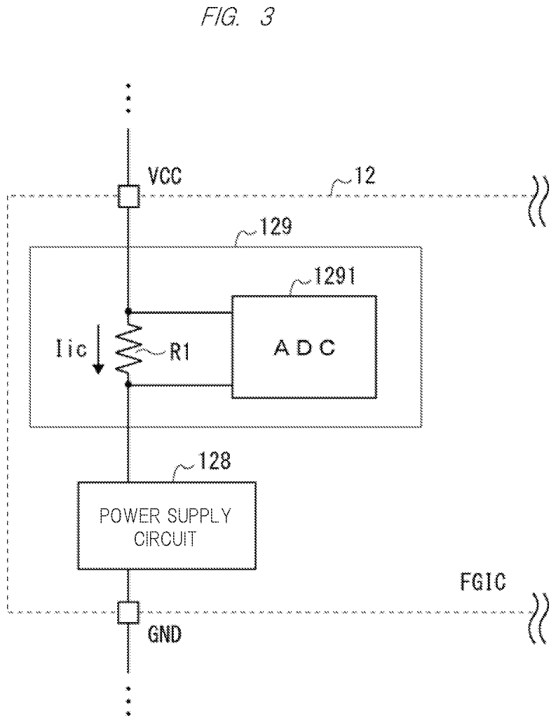

FIG. 3 is a diagram depicting a configurational example of a part of the battery management device 12. As shown in FIG. 3, the battery management device 12 further includes the current measurement circuit 129. The current measurement circuit 129 has at least, for example, a resistance element (first resistance element) R1 and an AD converter 1291.

The resistance element R1 is provided between the external terminal VCC and a high-potential-side terminal of the power supply circuit 128. Since the output voltage of the battery 11 is supplied from outside the battery management device 12 to the external terminal VCC, current supplied from the battery 11 to the battery management device 12 flows through the resistance element R1. The AD converter 1291 detects the potential difference between both ends of the resistance element R1. More specifically, the AD converter 1291 converts the potential difference between both ends of the resistance element R1 to a digital signal, and outputs it. Here, since the resistance value of the resistance element R1 is previously determined, the current value Iic of the current flowing through the resistance element R1 can be calculated from the potential difference between both ends of the resistance element R1 detected by the AD converter 1291. Thus, the result of detection made by the AD converter 1291 may be used as the result of measurement of the current value Iic of the current flowing through the resistance element R1.

The computing circuit 124 calculates a use capacity Quse of the battery 11 used in a period from the start of discharging to the end of discharge of the battery 11, based on an accumulation value of the current values Iic of the current flowing through the resistance element R1 (that is, current supplied from the battery 11 to the battery management device 12) and an accumulation value of the current values Isense of the current flowing through the resistance element Rs (that is, current supplied from the battery 11 to the load 50). The use capacity Quse is a capacity discharged in the period from the battery 11 from the start of discharging to the end of discharge of the battery 11. The use capacity Quse can be represented as the following Equation (1).

[Equation 1]

Qᵤₛₑ=∫Iₛₑₙₛₑdt+∫I_{ic}dt (1)

Also, a full-charge capacity Qmax of the battery 11 can be represented as the following Equation (2). Note that the full-charge capacity Qmax is a capacity discharged from the battery in a period from a full-charge state of the battery to a complete-discharge state. A term “SOCa” indicates a charge rate of the battery 11 at the start of discharge of the battery 11, and a term “SOCb” indicates a charge rate of the battery at the end of discharge of the battery 11.

$$\begin{matrix}[ Equation 2 ] & \\ {Q}_{max} = \frac{{Q}_{u s e}}{S O {C}_{a} - S O {C}_{b}} \times 100 & ( 2 )\end{matrix}$$

Here, a remaining capacity Qrem of the battery 11 is found by subtracting the use capacity Quse from the full-charge capacity Qmax. Therefore, the computing circuit 124 can calculate the remaining capacity Qrem based on the measurement result of each of the use capacity Quse and the full-charge capacity Qmax.

(Operation of Battery Management Device 12)

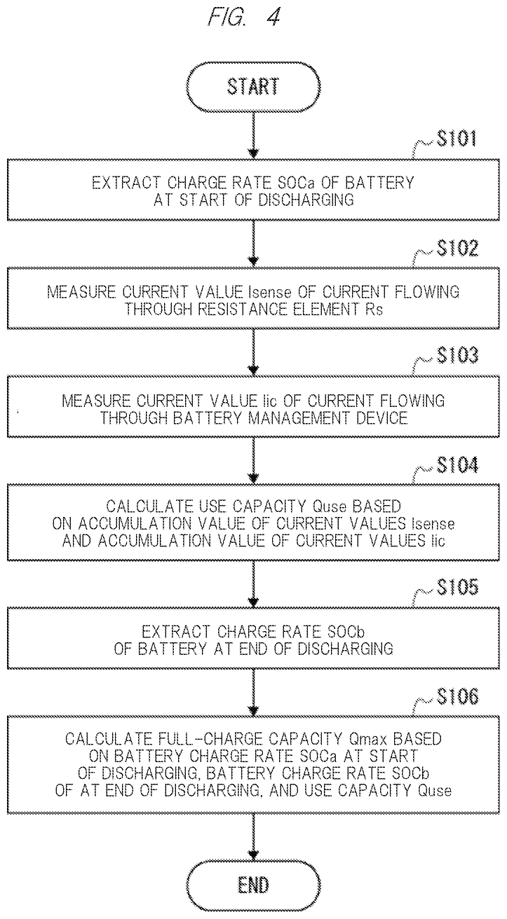

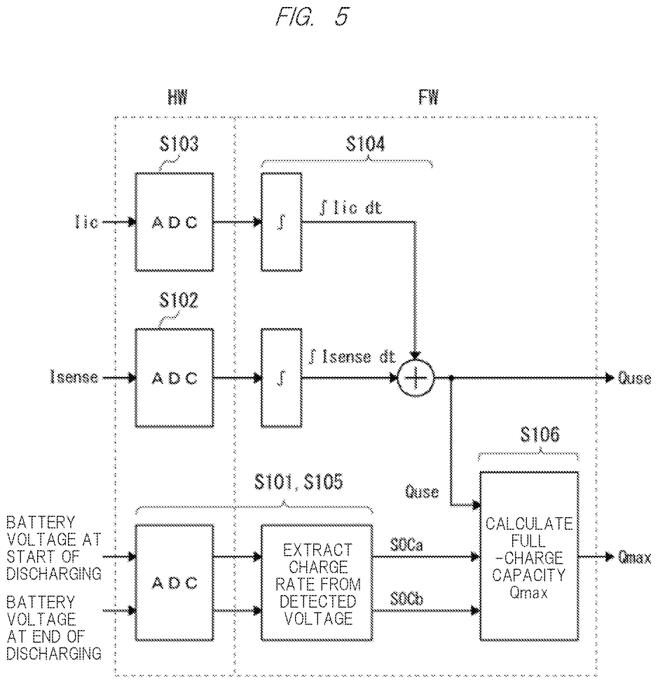

Next, the operation of the battery management device 12 will be described with reference to FIGS. 4 and 5. FIG. 4 is a flowchart depicting the operation of the battery management device 12. FIG. 5 is a block line diagram for describing the operation of the computing circuit 124 provided to the battery management device 12. As shown in FIG. 5, the operation of the battery management device 12 can be classified into operation in hardware (HW) and operation in firmware (FW). Note that processes at steps S101 to S106 shown in FIG. 5 correspond to processes at steps S101 to S106 shown in FIG. 4.

First, discharge of the battery 11 starts. At this time, the battery management device 12 measures output voltage of the battery 11 at the start of discharge of the battery 11. Here, the storage circuit 127 has stored therein information about the charge rate of the battery 11 corresponding to the output voltage of the battery 11. Thus, from the output voltage of the battery 11 at the start of discharge of the battery 11, the battery management device 12 can extract the charge rate SOCa of the battery 11 at the start of discharge of the battery 11 (step S101).

Then, in a period from the start of discharge to the end of discharge of the battery 11, the battery management device 12 measures the current value Isense of the current flowing through the resistance element Rs (that is, current supplied from the battery 11 to the load 50) (step S102).

Also, in the period from the start of discharge until the end of discharge of the battery 11, the battery management device 12 measures the current value Iic of the current flowing through the resistance element R1 (that is, current supplied from the battery 11 to the battery management device 12) (step S103).

Then, the battery management device 12 calculates the use capacity Quse of the battery 11 based on the accumulation value of the current values Isense and the accumulation value of the current values Iic in the period from the start of discharge to the end of discharge of the battery 11 (step S104). Specifically, the battery management device 12 calculates the use capacity Quse of the battery 11 by using the above-described Equation (1).

Also, the battery management device 12 measures output voltage of the battery 11 at the end of discharge of the battery 11. Here, the storage circuit 127 has stored therein information about the charge rate of the battery 11 corresponding to the output voltage of the battery 11. Thus, from the output voltage of the battery 11 at the end of discharge of the battery 11, the battery management device 12 can extract the charge rate SOCb of the battery 11 at the end of discharge of the battery 11 (step S105).

Here, the battery management device 12 calculates the full-charge capacity Qmax of the battery based on the battery charge rate SOCa at the start of discharge, the battery charge rate SOCb at the end of discharge, and the use capacity Quse of the battery 11 (step S106). Specifically, the battery management device 12 calculates the full-charge capacity Qmax of the battery 11 by using the above-described Equation (2). From the use capacity Quse and the full-charge capacity Qmax of the battery 11, the battery management device 12 can calculate the remaining capacity Qrem of the battery 11.

In this manner, the battery management device 12 measures the use capacity Quse and the full-charge capacity Qmax of the battery 11, based on not only the accumulation value of the current values Isense of consumed current of the load 50 but also the accumulation value of the current values Iic of self-consumed current in the period from the start of discharge to the end of discharge of the battery 11, and calculates the remaining capacity Qrem of the battery 11, based on these measurement results. With this, the battery management device 12 can more accurately calculate the remaining capacity Qrem of the battery 11 than that of a case of calculating the remaining capacity Qrem of the battery 11 without consideration of the current value Iic of self-consumed current. Thus, the battery management device 12 can accurately calculate the remaining capacity Qrem of the battery 11 even at activation after long storage such as product transportation.

### First Modification Example of Battery Management Device 12

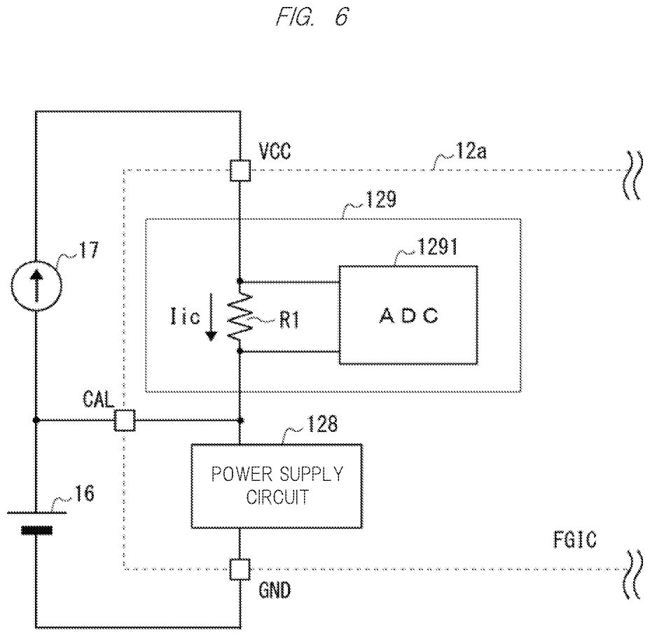

FIG. 6 is a diagram of a first modification example of the battery management device 12 depicted as a battery management device 12a. The battery management device 12a further includes an external terminal CAL. The external terminal CAL is connected to the high-potential-side terminal of the power supply circuit 128 and also connected to, of one terminal and the other terminal of the resistance element R1, the other terminal different from the one terminal connected to the external terminal VCC.

Outside the battery management device 12a, a constant current source 17 is provided between the external terminals CAL and VCC, and a battery 16 is provided between the external terminals CAL and GND. Note that an existing external terminal may be used in place of the external terminal CAL.

Note that operation mode of the battery management device 12a includes at least normal operation mode in which normal operation is performed and calibration mode in which calibration is performed. The battery management device 12a is configured so that, when the operation mode is the calibration mode, reference current generated by the constant current source 17 flows from the external terminal VCC via the resistance element R1 to the external terminal CAL. At this time, in the battery management device 12a, for example, the AD converter 1291 is adjusted to correctly detect the potential difference between both ends of the resistance element R1 determined by the resistance value of the resistance element R1 and the current value of the reference current. Other structures of the battery management device 12a are similar to those of the battery management device 12, and are thus not described herein.

### Second Modification Example of Battery Management Device 12

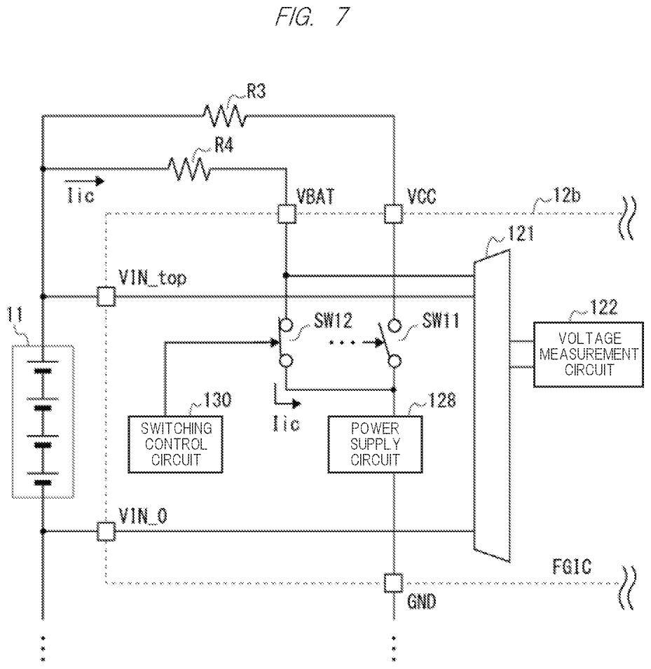

FIG. 7 is a diagram of a second modification example of the battery management device 12 depicted as a battery management device 12b. In comparison with the battery management device 12, the battery management device 12b does not include the resistance element R1 and the AD converter 1291 but includes switch elements SW11 and SW12 and a switching control circuit 130. In place of the resistance element R1, note that a resistance element R4 is provided outside the battery management device 12b. Also, in place of the AD converter 1291, the existing voltage measurement circuit 122 is used.

The switch element (first switch element) SW11 is provided between the external terminal VCC and the high-potential-side terminal of the power supply circuit 128. The switch element (second switch element) SW12 is provided between an external terminal VBAT and the high-potential-side terminal of the power supply circuit 128. The switching control circuit 130 switches the switch elements SW11 and SW12 to be turned ON and OFF by following, for example, an instruction output from the computing circuit 124.

Outside the battery management device 12b, the resistance element R4 having a resistance value larger than the resistance component R3 on a current path between the external terminal VCC and the positive-electrode-side terminal of the battery 11 is provided between the external terminal VBAT and the positive-electrode-side terminal of the battery 11. For example, while the resistance value of the resistance component R3 is about 10Ω, the resistance value of the resistance element R4 is about 1 kΩ that is large.

Other structures of the battery management device 12b are similar to those of the battery management device 12, and are thus not described herein.

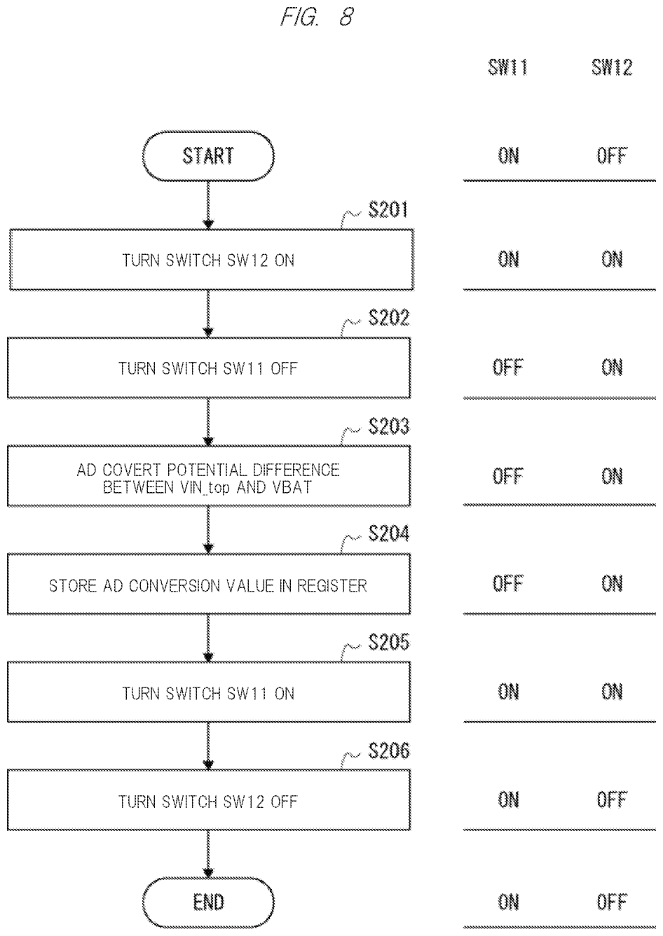

FIG. 8 is a flowchart depicting operation of measuring the current self-consumed by the battery management device 12b. Note that operation mode of the battery management device 12b includes at least self-consumed current measurement mode in which the self-consumed current is measured and normal operation mode in which normal operation is performed without the measurement of the self-consumed current.

First, when the operation mode is the normal operation mode, the battery management device 12b turns the switch element SW11 ON and the switch element SW12 OFF. With this, the output voltage of the battery 11 is supplied to the power supply circuit 128 via the external terminal VCC.

Then, the operation mode of the battery management device 12b is switched from the normal operation mode to the self-consumed current measurement mode. Accordingly, the battery management device 12b switches the switch element SW12 from the OFF state to the ON state (step S201) and switch the switch element SW11 from the ON state to the OFF state (step S202). With this, current flows from the battery 11 via the resistance element R4 having the large resistance value to the battery management device 12b. Also, at this time, the selector 121 selects and outputs a potential difference of each of the external terminals VBAT and VIN_top. That is, at this time, the selector 121 selects and outputs a potential difference between both ends of the resistance element R4. With this, the voltage measurement circuit 122 detects the potential difference between both ends of the resistance element R4. More specifically, the voltage measurement circuit 122 is an AD converter that converts the potential difference between both ends of the resistance element R4 to a digital signal and that outputs it (step S203). Here, since the resistance value of the resistance element R4 is previously determined, the current value Iic of the current flowing through the resistance element R4 can be calculated from the potential difference between both ends of the resistance element R4 detected by the voltage measurement circuit 122. Thus, the result of measurement by the voltage measurement circuit 122 may be used as the result of measurement of the current value Iic of the current flowing through the resistance element R4. Note that the result (AD conversion value) of measurement by the voltage measurement circuit 122 is stored in a register, and is used for the calculation of the use capacity. Then, the battery management device 12b switches the switch element SW11 from the OFF state to the ON state (step S205) and switches the switch element SW12 from the ON state to the ON state (step S206). With this, the operation mode of the battery management device 12b is switched from the self-consumed current measurement mode to the normal operation mode.

In this manner, the battery management device 12b can exert effects as almost the same as those of the battery management device 12. Also, by using the resistance element R4 having the large resistance value, the battery management device 12b can more accurately measure the current value Iic of the self-consumed current. Furthermore, the battery management device 12b is unnecessary to include the resistance element R4 having the large resistance value, and thus, a circuit scale can be downsized.

### Third Modification Example of Battery Management Device 12

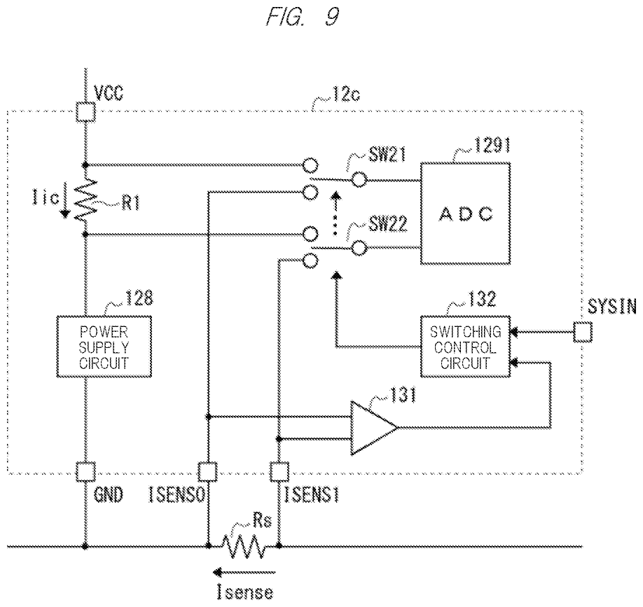

FIG. 9 is a diagram of a third modification example of the battery management device 12 depicted as a battery management device 12c. In comparison with the battery management device 12, the battery management device 12c further includes switch elements SW21 and SW22, a comparator circuit 131, and a switching control circuit 132. Also, the battery management device 12c does not include the current measurement circuit 123, and the AD converter 1291 also plays as a role of the current measurement circuit 123.

The switch elements SW21 and SW22 each plays a role of a selector which selects and outputs either one of the potential difference between both ends of the resistance element R1 and the potential difference between both ends of the resistance element Rs. Specifically, the switch element SW21 is provided so as to selectively allow either one terminal of the resistance element R1 or one terminal of the resistance element Rs to be connected to one input terminal of the AD converter 1291. The switch element SW22 is provided so as to selectively allow either the other terminal of the resistance element R1 or the other terminal of the resistance element Rs to be connected to the other input terminal of the AD converter 1291. The comparator circuit 131 compares the potentials at both ends of the resistance element Rs. The switching control circuit 132 switches, for example, the switch elements SW21 and SW22 between the ON state and the OFF state, based on the result of comparison made by the comparator circuit 131, information acquired from outside via an external terminal SYSIN, or the like in addition to the instruction made by the computing circuit 124.

Other structures of the battery management device 12c are similar to those of the battery management device 12, and are thus not described herein.

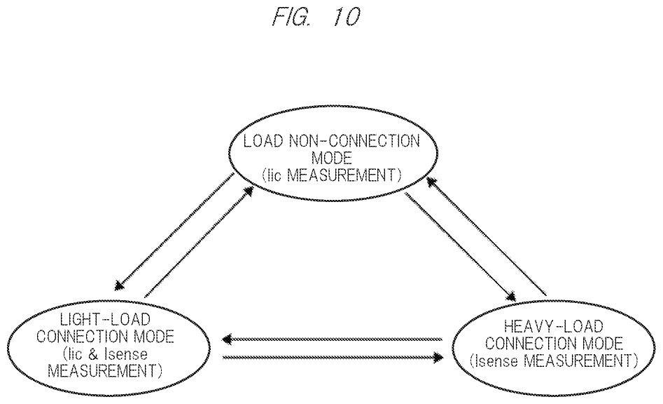

FIG. 10 is a diagram for describing operation mode of the battery management device 12c. As shown in FIG. 10, the operation mode of the battery management device 12c includes load non-connection mode (first mode) in which the battery 11 is not connected to the load 50, heavy-load connection mode (second mode) in which the battery 11 is connected to the load 50 that is normally operating, and light-load connection load (third mode) in which the battery 11 is connected to the load 50 that stops operating.

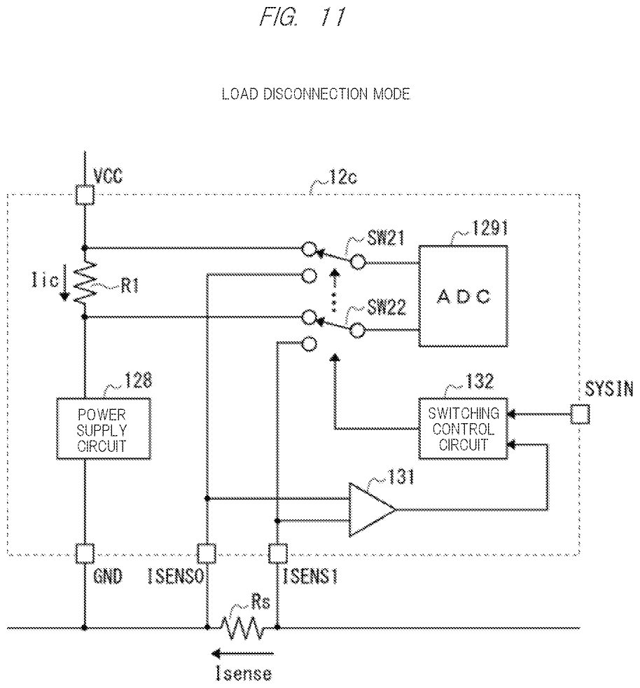

First, the operation of the battery management device 12c in the case of the load non-connection mode as the operation mode of the battery management device 12c is described with reference to FIG. 11. FIG. 11 is a diagram depicting a state of the battery management device 12c in the load non-connection mode.

In the load non-connection mode, the battery 11 is not connected to the load 50. When the battery 11 is not connected to the load 50, the current value Isense of the current supplied from the battery 11 to the load 50 is substantially 0 A. On the other hand, since the battery management device 12c keeps operating, the current value Iic of the current supplied from the battery 11 to the battery management device 12c is dominant in the current value Isense. At this time, the switching control circuit 132 determines that the operation mode is the load non-connection mode by, for example, via the external terminal SYSIN, receiving information indicating that the load 50 is not connected to the battery 11 or receiving the result of comparison from the comparator circuit 131 indicating that the potential difference between both ends of the resistance element Rs is close to 0 V (that is, current does not flow through the resistance element Rs).

In this case, the switching control circuit 132 causes the switch elements SW21 and SW22 to select the potential difference between both ends of the resistance element R1 and to output it toward the AD converter 1291. With this, the AD converter 1291 detects the potential difference between both ends of the resistance element R1. More specifically, the AD converter 1291 converts the potential difference between both ends of the resistance element R1 to a digital signal. Here, since the resistance value of the resistance element R1 is previously determined, the current value Iic of the current flowing through the resistance element R1 can be calculated from the potential difference between both ends of the resistance element R1 detected by the AD converter 1291. Thus, the result of detection made by the AD converter 1291 may be used as the result of measurement of the current value Iic of the current flowing through the resistance element R1.

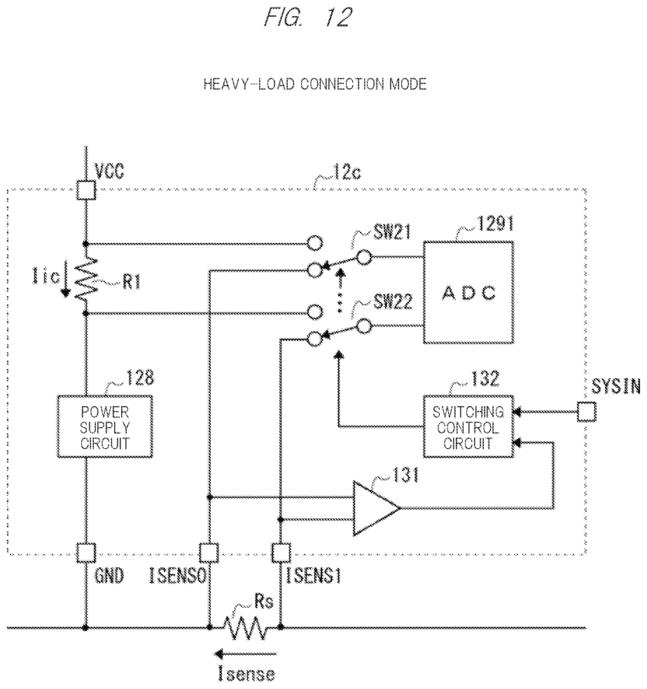

Next, the operation of the battery management device 12c in the case of the heavy-load connection mode as the operation mode of the battery management device 12c is described with reference to FIG. 12. FIG. 12 is a diagram depicting a state of the battery management device 12c in the heavy-load connection mode.

In the heavy-load connection mode, the battery 11 is connected to the load 50 that is normally operating. In this case, current consumed by the load 50 is large. That is, the current value Isense of the current supplied from the battery 11 to the load 50 is dominant in the current value Iic supplied from the battery 11 to the battery management device 12c. At this time, the switching control circuit 132 determines that the operation mode is the heavy-load connection mode by, for example, via the external terminal SYSIN, receiving information indicating that the load 50 is connected to the battery 11 or receiving the result of comparison from the comparator circuit 131 indicating that the potential difference between both ends of the resistance element Rs is equal to or larger than a predetermined value (that is, the current value Isense is equal to or larger than a predetermined value).

In this case, the switching control circuit 132 causes the switch elements SW21 and SW22 to select the potential difference between both ends of the resistance element Rs and to output it toward the AD converter 1291. With this, the AD converter 1291 detects the potential difference between both ends of the resistance element Rs. More specifically, the AD converter 1291 converts the potential difference between both ends of the resistance element Rs to a digital signal. Here, since the resistance value of the resistance element Rs is previously determined, the current value Isense of the current flowing through the resistance element Rs can be calculated from the potential difference between both ends of the resistance element Rs detected by the AD converter 1291. Thus, the result of detection made by the AD converter 1291 may be used as the result of measurement of the current value Isense of the current flowing through the resistance element Rs.

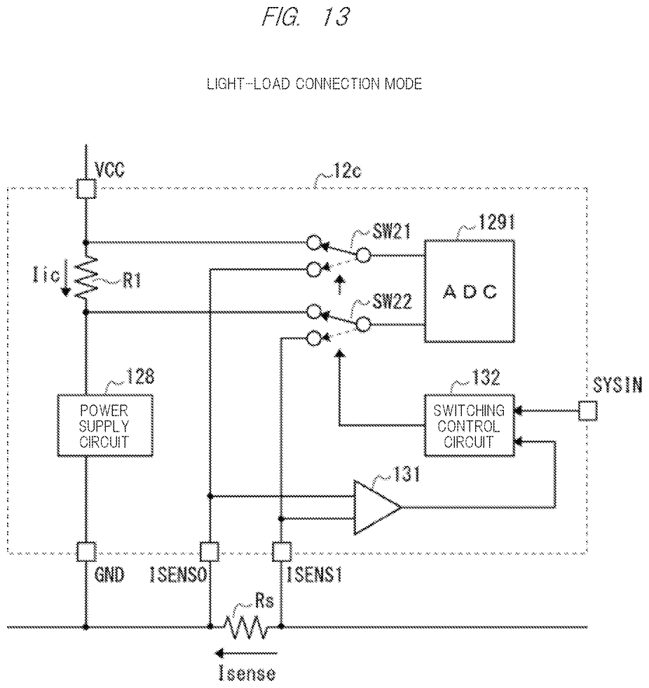

Next, the operation of the battery management device 12c in the case of the light-load connection mode as the operation mode of the battery management device 12c is described with reference to FIG. 13. FIG. 13 is a diagram depicting a state of the battery management device 12c in the light-load connection mode.

In the light-load connection mode, the battery 11 is connected to the load 50 that stops operating. The load 50 that stops operating means the load 50 in, for example, a sleep state or its corresponding state. In this case, since neither the current value Isense nor the current value Iic is negligible, both of the current value Isense and the current value Iic are measured. Here, in the light-load connection mode, since the operation of the load 50 is limited to a predetermined stationary operation, each fluctuation of the current value Isense and the current value Iic is small. Thus, the battery management device 12c alternately measures the current value Isense and the current value Iic, and calculates accumulation values of the current values Isense and Iic in a period of the light-load connection mode after estimating the current value Iic during the measurement of the current value Isense from the measurement value of the current value Iic or the like and estimating the current value Isense during the measurement of the current value Iic from the measurement value of the current value Isense or the like.

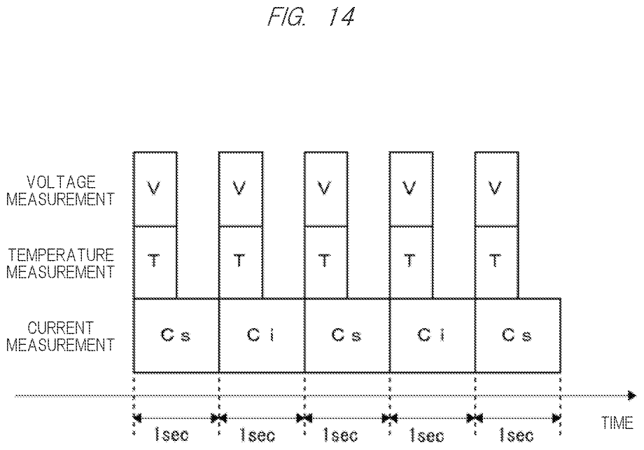

FIG. 14 is a timing chart depicting one example of operation of the battery management device 12c in the light-load connection mode. In FIG. 14, a term “V” represents measurement of battery voltage, a term “T” represents measurement of battery temperature, a term “Cs” represents the measurement of the current value Isense, and a term “Ci” represents the measurement of the current value Iic.

In the example of FIG. 14, the battery management device 12c measures the current value Isense and the current value Iic while switching these measurements for every one second. Also, the battery management device 12c measures both the battery voltage and the battery temperature for every other second. Note that the measurement of the current value Isense and the measurement of the current value Iic may be switched for not every one second but predetermined time.

For example, when a period of the light-load connection mode is twenty seconds, the measurement time of the current value Isense is ten seconds, and the measurement time of the current value Iic is ten seconds. However, also during measurement of the current value Isense, current is supplied from the battery 11 to the battery management device 12c. Similarly, also during measurement of the current value Iic, current is supplied from the battery 11 to the load 50. Thus, the battery management device 12c calculates an accumulation value of the current values Isense in the period (here, twenty seconds) of the light-load connection mode after estimating the current value Isense during the measurement of the current value Iic from the measurement value of the current value Isense or the like. Similarly, the battery management device 12c calculates an accumulation value of the current value Iic in the period (here, twenty seconds) of the light-load connection mode after estimating the current value Iic during the measurement of the current value Isense from the measurement value of the current value Iic or the like.

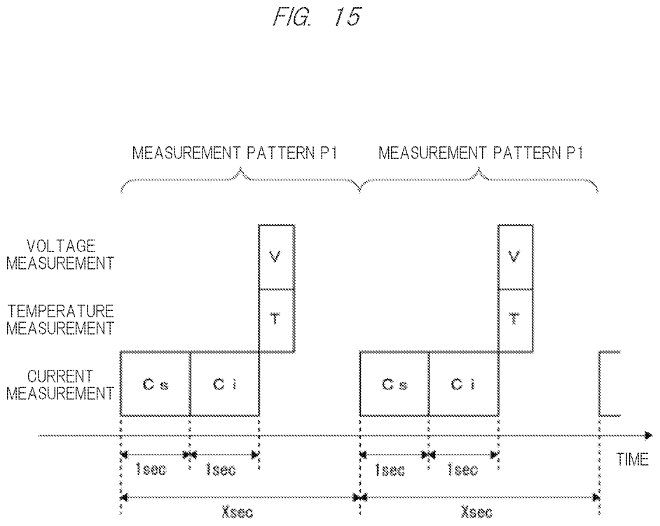

FIG. 15 is a timing chart depicting another example of operation of the battery management device 12c in the light-load connection mode. In FIG. 15, a term “V” represents measurement of battery voltage, a term “T” represents measurement of battery temperature, a term “Cs” represents measurement of the current value Isense, and a term “Ci” represents measurement of the current value Iic.

In the example of FIG. 15, the battery management device 12c performs the measurement of the current value Isense, the measurement of the current value Iic, the measurement of the battery voltage, and the measurement of the battery temperature at a predetermined cycle (for every X seconds). More specifically, as a first measurement pattern P1, in one cycle, the battery management device 12c performs the measurement of the current value Isense first, performs the measurement of the current value Iic next, and then, simultaneously performs the measurement of the battery voltage and the measurement of the battery temperature. A method of calculating an accumulation value of the current values Isense and a method of calculating an accumulation value of the current values Iic are basically similar to those of the example of FIG. 14, and thus, are not described herein. Note that the measurements of the current values Isense and Iic are performed not only in a predetermined cycle, and may be performed at a timing at which the degree of temperature change exceeds a threshold in consideration of the fact that the consumed current of the power supply circuit 128 has large temperature dependency.

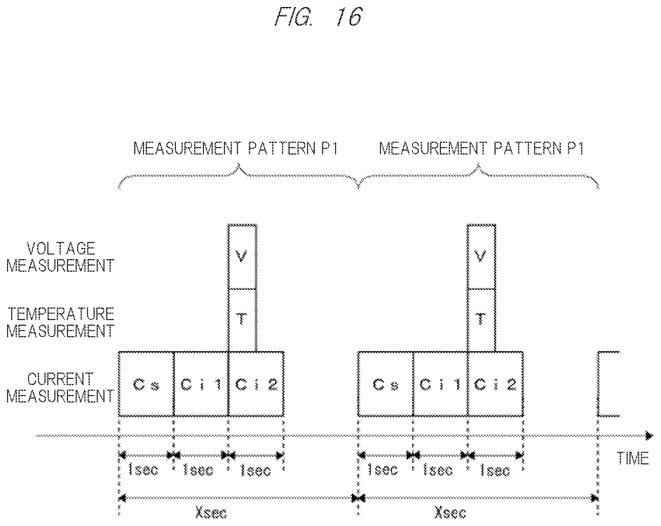

FIG. 16 is a timing chart depicting still another example of operation of the battery management device 12c in the light-load connection mode. In FIG. 16, a term “V” represents measurement of battery voltage, a term “T” represents measurement of battery temperature, a term “Cs” represents measurement of the current value Isense, and terms “Ci1” and “Ci2” represent measurement of the current value Iic. Here, the term “Ci1” represents measurement of the current value Iic to be singly performed, and the term “Ci2” represents measurement of the current value Iic to be simultaneously performed with the measurement of the battery voltage and the measurement of the battery temperature.

In the example of FIG. 16, the battery management device 12c performs measurement of the current value Isense, measurement of the current value Iic, measurement of battery voltage, and measurement of battery temperature in a predetermined cycle (for every X seconds). More specifically, as a second measurement pattern P2, in one cycle, the battery management device 12c performs the measurement of the current value Isense first, performs the measurement of the current value Iic next, and then, simultaneously performs the measurement of the current value Iic, the measurement of the battery voltage and the measurement of the battery temperature. With this, an accumulation value of the current values Iic can be calculated in consideration of the fact that the consumed current is transiently increased by the measurement of the battery voltage and the measurement of the battery temperature.

In this case, the use capacity Quse of the battery 11 in the light-load connection mode can be represented as the following Equation (3). Note that Iic1 indicates a measurement value of the current value Iic singly measured, and Iic2 indicates a measurement value of the current value Iic measured simultaneously with the measurement of the battery voltage and the measurement of the battery temperature.

$$\begin{matrix}[ Equation 3 ] & \\ {Q}_{u s e} = \int {I}_{s e n s e} dt + \int \frac{( {I}_{i c 2} \times 1 ) + ( {I}_{i c 1} \times ( X - 1 ) )}{X} dt & ( 3 )\end{matrix}$$

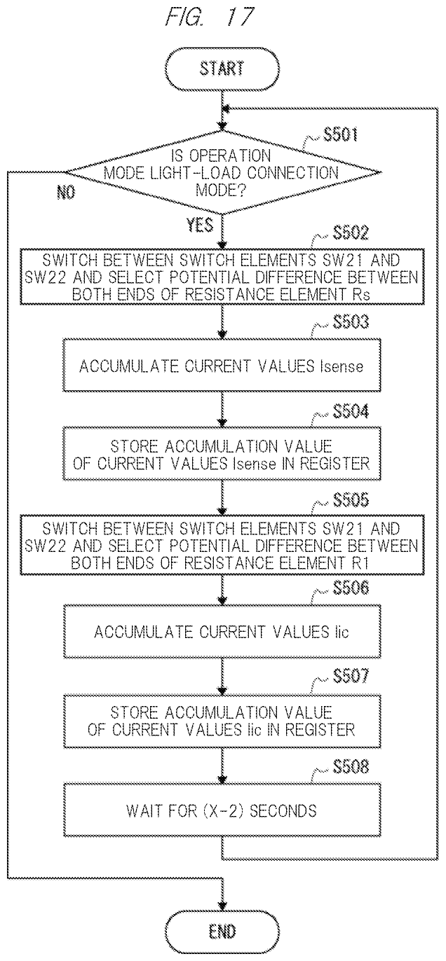

FIG. 17 is a flowchart depicting operation of the battery management device 12c in the light-load connection mode. The operation of FIG. 17 corresponds to the operation of FIG. 15.

First, when the operation mode becomes the light-load connection mode (YES at step S501), the battery management device 12c causes the switch elements SW21 and SW22 to select the potential difference between both ends of the resistance element Rs and to output it toward the AD converter 1291 (step S502). With this, the AD converter 1291 detects the potential difference between both ends of the resistance element Rs. More specifically, the AD converter 1291 converts the potential difference between both ends of the resistance element Rs to a digital signal. Here, since the resistance value of the resistance element Rs is previously determined, the current value Isense of the current flowing through the resistance element Rs can be calculated from the potential difference between both ends of the resistance element Rs detected by the AD converter 1291. Thus, the result of detection made by the AD converter 1291 may be used as the result of measurement of the current value Isense of the current flowing through the resistance element Rs. The measured current values Isense are accumulated (step S503) and are stored in a register (step S504). The accumulation value of the current values Isense stored in the register is used for calculation of the use capacity Quse of the battery 11 in the period of the light-load connection mode after the end of the light-load connection mode.

Then (in the present example, after a lapse of one second), the battery management device 12c causes the switch elements SW21 and S22 to select the potential difference between both ends of the resistance element R1 and to output it toward the AD converter 1291 (step S505). With this, the AD converter 1291 detects the potential difference between both ends of the resistance element R1. More specifically, the AD converter 1291 converts the potential difference between both ends of the resistance element R1 to a digital signal. Here, since the resistance value of the resistance element R1 is previously determined, the current value Iic of the current flowing through the resistance element R1 can be calculated from the potential difference between both ends of the resistance element R1 detected by the AD converter 1291. Thus, the result of detection made by the AD converter 1291 may be used as the result of measurement of the current value Iic of the current flowing through the resistance element R1. The measured current values Iic are accumulated (step S506) and are stored in a register (step S507). The accumulation value of the current values Iic stored in the register is used for calculation of the use capacity Quse of the battery 11 in the period of the light-load connection mode after the end of the light-load connection mode.

Then (in the present example, after a lapse of two seconds), the process waits until “X−2” seconds past (step S508). After the waiting, when the operation mode is the light-load connection mode, processes of step S502 to S508 are performed in the next cycle. Then, when the operation mode is not the light-load connection mode anymore (No at step S501), the battery management device 12c calculates the use capacity Quse of the battery 11 in the period of the light-load connection mode to complete the operation.

In this manner, since the battery management device 12c can measure the current values Iic and Isense by using the common AD converter 1291, the increase in the circuit scale can be suppressed. Also, since the battery management device 12c intermittently measures each of the current values Iic and Isense, the measurement time can be made shorter than that in a case in which each of the current values Iic and Isense is measured at any time.

### Fourth Modification Example of Battery Management Device 12

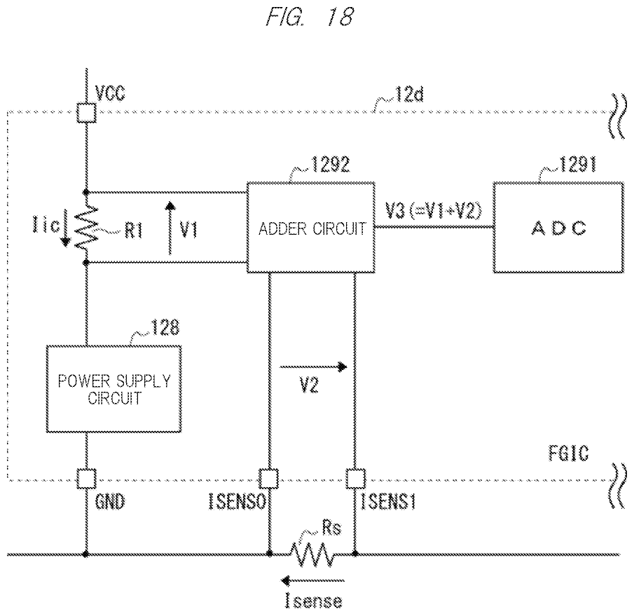

FIG. 18 is a diagram of a fourth modification example of the battery management device 12 depicted as a battery management device 12d. In comparison with the battery management device 12, the battery management device 12d further includes an adder circuit 1292. Also, the battery management device 12d does not include the current measurement circuit 123, and the AD converter 1291 also plays a role of the current measurement circuit 123.

The adder circuit 1292 adds a potential difference V1 between both ends of the resistance element R1 and a potential difference V2 between both ends of the resistance element Rs, and outputs its result. The AD converter 1291 detects the addition result V3 (=V1+V2) made by the adder circuit 1292. More specifically, the AD converter 1291 converts the addition result V3 made by the adder circuit 1292 to a digital signal, and outputs it. Here, since the resistance values of the resistance elements R1 and Rs are each previously determined, a total value of the current values Iic and Isense of the current flowing through the resistance elements R1 and Rs, respectively, can be calculated from the potential difference V3 detected by the AD converter 1291. Thus, the result of detection made by the AD converter 1291 may be used as the result of measurement of the total value of the current values Iic and Isense of the current flowing through the resistance elements R1 and Rs, respectively.

In the battery management device 12d, the resistance values of the resistance elements R1 and Rs need to be substantially equal to each other, or the potential difference between both ends of the resistance element Rs needs to be amplified. However, since the current values Iic and Isense can be measured by the common AD converter 1291, the increase in the circuit scale can be suppressed. Also, in the battery management device 12d, the results of measurements of the current values Iic and Isense are collected to be one measurement result, and thus, a firmware identical to that used when the remaining capacity of the battery 11 is calculated by using only, for example, the result of measurement of the current value Isense can be used as it is.

### Fifth Modification Example of Battery Management Device 12

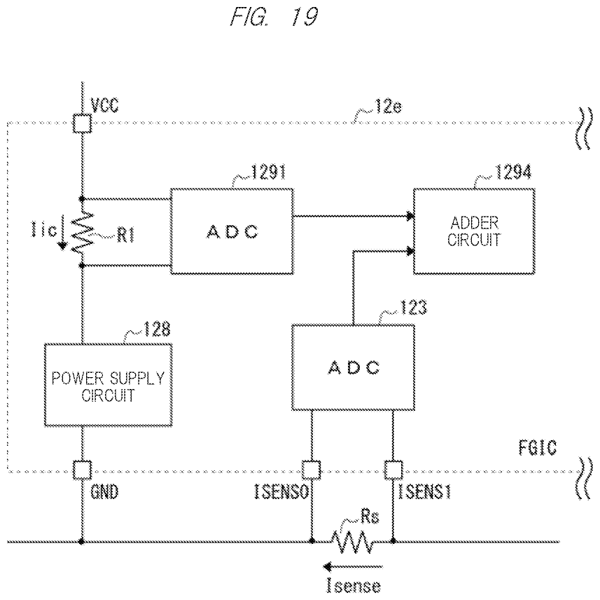

FIG. 19 is a diagram of a fifth modification example of the battery management device 12 depicted as a battery management device 12e. In comparison with the battery management device 12, the battery management device 12e further includes an adder circuit 1294.

The adder circuit 1294 adds the result of detection made by the AD converter 1291 (that is the digital signal corresponding to the potential difference between both ends of the resistance element R1) and the result of detection made by the current measurement circuit 123 as the AD converter (that is the digital signal corresponding to the potential difference between both ends of the resistance element Rs), and outputs its result. The result of addition made by the adder circuit 1294 may be used as the result of measurement of a total value of the current values Iic and Isense of the current flowing through the resistance elements R1 and Rs, respectively.

In the battery management device 12e, the results of measurements of the current values Iic and Isense are collected to be one measurement result, and thus, a firmware identical to that used when the remaining capacity of the battery 11 is calculated by using only, for example, the result of measurement of the current value Isense can be used as it is.

### Second Embodiment

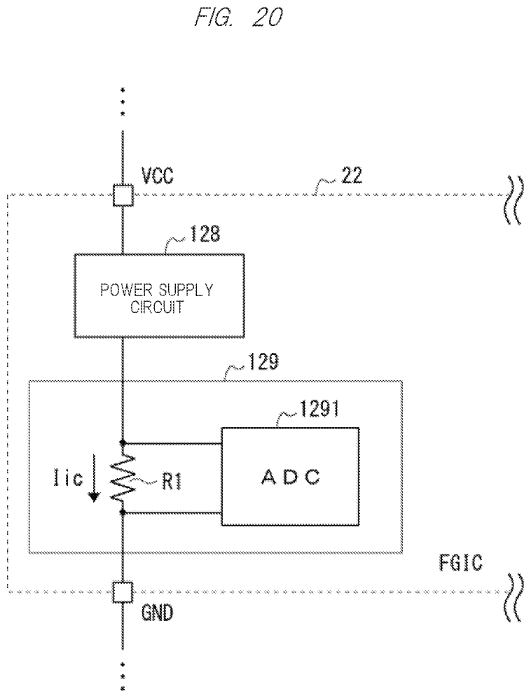

FIG. 20 is a diagram depicting a configurational example of a part of a battery management device 22 according to a second embodiment. While the battery management device 12 has the resistance element R1 provided between the external terminal VCC and the high-potential-side terminal of the power supply circuit 128, the battery management device 22 has the resistance element R1 provided between the external terminal GND and a low-potential-side power supply terminal of the power supply circuit 128. Other structures of the battery management device 22 are similar to those of the battery management device 12, and are thus not described herein.

The battery management device 22 can exert effects as almost the same as those of the battery management device 12. Note that also in the battery management devices 12a to 12e, the current measurement circuit 129 or its equivalent circuit may be provided between the external terminal GND and the low-potential-side terminal of the power supply circuit 128 in place of being provided between the external terminal VCC and the high-potential-side terminal of the power supply circuit 128.

### Third Embodiment

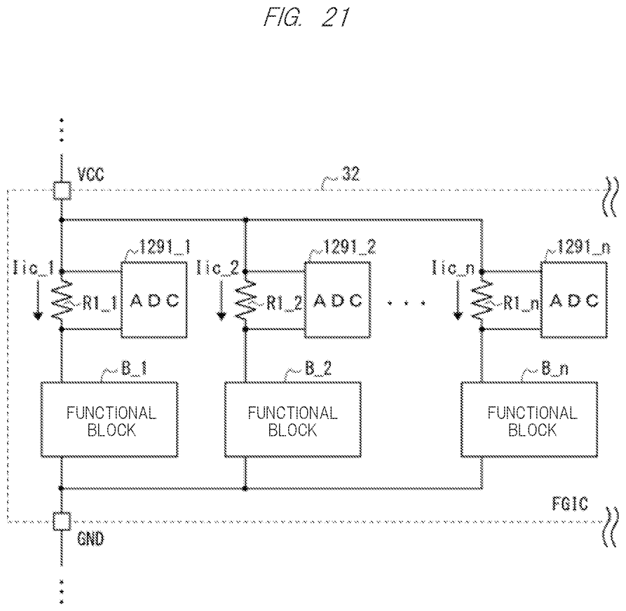

FIG. 21 is a diagram depicting a configurational example of a part of a battery management device 32 according to a third embodiment. While the battery management device 12 has the resistance element R1 provided between the external terminal VCC and the high-potential-side terminal of the power supply circuit 128, the battery management device 32 has “n” resistance elements (“n” is an integer equal to or larger than 2) R1_1 to R1_n provided between the external terminal VCC and high-potentially-side external terminals of “n” functional blocks B_1 to B_n, respectively. Note that the functional blocks B_1 to B_n are internal circuits of the battery management device 32, and each includes, for example, the computing circuit 124, the charge/discharge control circuit 125, and so forth.

Also, in place of the AD converter 1291, the battery management device 32 has “n” AD converters 1291_1 to 1291_n each of which detects a potential difference between both ends of each of the resistance elements R1_1 to R1_n. Other structures of the battery management device 32 are similar to those of the battery management device 12, and are thus not described herein.

Here, since the resistance values of the resistance elements R1_1 to R1_n are previously determined, current values Iic_1 to Iic_n of the current flowing through the resistance elements R1_1 to R1_n can be calculated from the results of detections made by the AD converters 1291_1 to 1291_n, respectively. Thus, the results of detections made by the AD converters 1291_1 to 1291_n may be used as the results of measurements of the current values Iic_1 to Iic_n of the current flowing through the resistance elements R1_1 to R1_n, respectively. Note that a total value of the current values Iic_1 to Iic_n corresponds to the current value Iic.

The battery management device 32 can exert effects as almost the same as those of the battery management device 12. Also, since the battery management device 32 can detect the current value of the current supplied to each functional block, a failed functional block can be identified.

### Modification Example of Battery Management Device 32

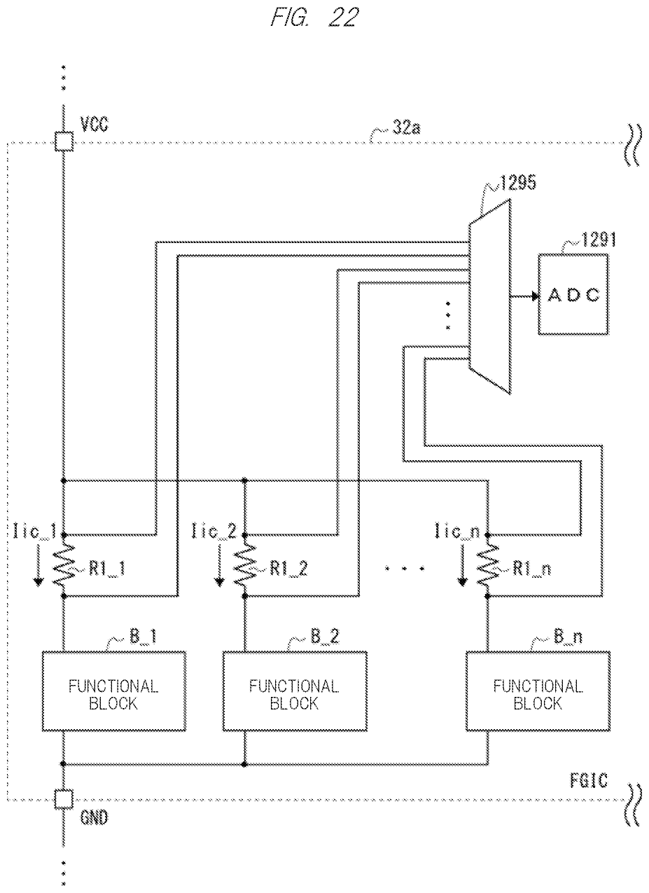

FIG. 22 is a diagram of a modification example of the battery management device 32 depicted as a battery management device 32a. The battery management device 32a includes a selector 1295 and one AD converter 1291 in place of the plurality of AD converters 1291_1 to 1291_n. The selector 1295 selectively outputs any of the potential differences between both ends of the resistance elements R1_1 to R1_N. The AD converter 1291 detects the potential difference selected by the selector 1295. Other structures of the battery management device 32a are similar to those of the battery management device 32, and are thus not described herein. The battery management device 32a can exert effects as almost the same as those of the battery management device 32.

### Fourth Embodiment

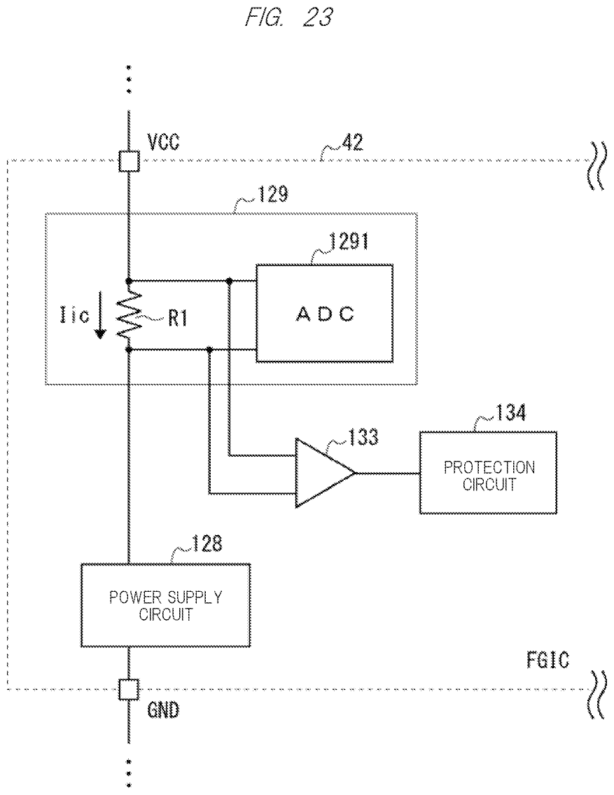

FIG. 23 is a diagram depicting a configurational example of a part of a battery management device 42 according to a fourth embodiment. The battery management device 42 further includes a comparator circuit 133 which compares the potentials at both ends of the resistance element R1 and a protection circuit 134 which protects the battery management device 42 from at least either overvoltage or overcurrent supplied from the battery 11 to the battery management device 42 when the result of comparison indicating that the potential difference between both ends of the resistance element R1 is equal to or larger than a threshold value is output from the comparator circuit 133. Other structures of the battery management device 42 are similar to those of the battery management device 12, and are thus not described herein.

The battery management device 42 can exert effects as almost the same as those of the battery management device 12. Also, the battery management device 42 can protect the battery management device 42 from at least either overvoltage or overcurrent supplied from the battery 11 to the battery management device 42.

The present invention is not limited to the above-described embodiments and is appropriately variable within a scope of the present invention.

Also, in the present disclosure, a part of or entire processes of the battery management device 12 can be achieved by causing a central processing unit (CPU) to execute a computer program.

The above-described program includes an instruction group (or software code) for causing a computer to perform one or more functions described in the embodiments when being read into the computer. The program may be stored in a non-transitory computer-readable medium or substantial storage medium. The computer-readable medium or substantial storage medium is not limited but exemplified as a random-access memory (RAM), read-only memory (ROM), flash memory, solid-state drive (SSD), any other memory technologies, CD-ROM, digital versatile disc (DVD), Blu-ray (registered trademark), disc, any other optical disc storage, magnetic cassette, magnetic tape, magnetic disk storage, or any other magnetic storage device. The program may be transmitted on a transitory computer-readable medium or communication medium. The transitory computer-readable medium or communication medium is not limited but exemplified as a propagation signal of an electrical, optical, audio, or any other form.

What is claimed is:

1. A semiconductor device comprising:
a current measurement circuit configured to measure a current value of a first current supplied from a battery to the semiconductor device that is a host device and a current value of a second current supplied from the battery to a load; and
a computing circuit configured to calculate a remaining capacity of the battery, based on an accumulation value of the first current and an accumulation value of the second current in a period from start of discharging to end of discharging in the battery.

2. The semiconductor device according to claim 1, further comprising
a storage circuit configured to store information about a charge rate of the battery in accordance with an output voltage of the battery,
wherein the computing circuit calculates the remaining capacity of the battery, based on, in addition to the accumulation value of the first current and the accumulation value of the second current in the period from the start of discharging to the end of discharging in the battery, a charge rate of the battery extracted from the storage circuit in accordance with an output voltage of the battery at the start of discharging in the battery and a charge rate of the battery extracted from the storage circuit in accordance with an output voltage of the battery at the end of discharging in the battery.

3. The semiconductor device according to claim 1,
wherein the current measurement circuit includes:
a first resistance element provided between a first external terminal to which an output voltage of the battery is supplied and a high-potential-side terminal of a power supply circuit configured to generate an operating voltage of an internal circuit of the semiconductor device; and
an AD converter configured to detect a potential difference between both ends of the first resistance element,
wherein a current value in accordance with a result of detection made by the AD converter is used as a result of measurement made by the current measurement circuit indicating the current value of the first current.

4. The semiconductor device according to claim 3, further comprising
a second external terminal connected to the other terminal of the first resistance element, the other terminal being different from one terminal of the first resistance element connected to the first external terminal, and also to the high-potential-side terminal of the power supply circuit,
wherein the semiconductor device is configured so that a reference current flows from the first external terminal via the first resistance element to the second external terminal when operation mode is calibration mode of the calibration mode and normal operation mode.

5. The semiconductor device according to claim 1, further comprising:
a first switch element provided between a first external terminal to which an output voltage of the battery is supplied and a high-potential-side terminal of a power supply circuit configured to generate an operating voltage of an internal circuit of the semiconductor device;
a second switch element provided between the high-potential-side terminal of the power supply circuit and a third external terminal to which the output voltage of the battery is suppled via a third resistance element having a resistance value larger than a resistance value of a resistance component on a current path connecting the battery and the load; and
a switching control circuit configured to turn the first switch element ON and turn the second switch element OFF when operation mode is normal operation mode of the normal operation mode and self-consumed current measurement mode, and turn the first switch element OFF and turn the second switch element ON when the operation mode is the self-consumed current measurement mode;
a selector configured to select and output a potential difference between a positive-electrode-side terminal of the battery and the third external terminal at least when the operation mode is the self-consumed current measurement mode; and
an AD converter configured to detect the potential difference selected by the selector,
wherein a current value in accordance with a result of detection made by the AD converter when the operation mode is the self-consumed current measurement mode is used as a result of measurement made by the current measurement circuit indicating a current value of the first current.

6. The semiconductor device according to claim 1,
wherein the current measurement circuit includes:
a first resistance element provided between a first external terminal to which an output voltage of the battery is supplied and a high-potential-side terminal of a power supply circuit configured to generate an operating voltage of an internal circuit of the semiconductor device;
a selector configured to selectively output either a potential difference between both ends of the first resistance element or a potential difference between both ends of a second resistance element which is provided on a current path connecting the battery and the load and through which the second current supplied from the battery to the load flows;
a switching control circuit configured to control selection of the selector in accordance with operation mode; and
an AD converter configured to detect the potential difference selected by the selector, and
wherein a current value in accordance with the potential difference between both ends of the first resistance element detected by the AD converter is used as a result of measurement made by the current measurement circuit indicating the current value of the first current, and a current value in accordance with the potential difference between both ends of the second resistance element detected by the AD converter is used as a result of measurement made by the current measurement circuit indicating the current value of the second current.

7. The semiconductor device according to claim 6,
wherein the switching control circuit causes the selector to select and output the potential difference between both ends of the first resistance element when the operation mode is first mode of the first mode in which the battery is not connected to the load, second mode in which the battery is connected to the load that is normally operating, and third mode in which the battery is connected to the load that stops operating, causes the selector to select and output the potential difference between both ends of the second resistance element when the operation mode is the second mode, and causes the selector to cyclically switch between the potential difference between both ends of the first resistance element and the potential difference between both ends of the second resistance element and select and output the potential difference when the operation mode is the third mode.

8. The semiconductor device according to claim 1,
wherein the current measurement circuit includes:
a first resistance element provided between a first external terminal to which an output voltage of the battery is supplied and a high-potential-side terminal of a power supply circuit configured to generate an operating voltage of an internal circuit of the semiconductor device;
an adder circuit configured to add a potential difference between both ends of the first resistance element and a potential difference between both ends of a second resistance element which is provided on a current path connecting the battery and the load and through which the second current supplied from the battery to the load flows; and
an AD converter configured to detect a result of addition made by the adder circuit, and
wherein a current value in accordance with the result of detection made by the AD converter is used as a result of measurement made by the current measurement circuit indicating a total value of the current value of the first current and the current value of the second current.

9. The semiconductor device according to claim 1,
wherein the current measurement circuit includes:
a first resistance element provided between a first external terminal to which an output voltage of the battery is supplied and a high-potential-side terminal of a power supply circuit configured to generate an operating voltage of an internal circuit of the semiconductor device;
a first AD converter configured to detect a potential difference between both ends of the first resistance element;
a second AD converter configured to detect a potential difference between both ends of a second resistance element which is provided on a current path connecting the battery and the load and through which the second current supplied from the battery to the load flows; and
an adder circuit configured to add a result of detection made by the first AD converter and a result of detection made by the second AD converter, and
wherein a current value in accordance with the result of addition made by the adder circuit is used as a result of measurement made by the current measurement circuit indicating a total value of the current value of the first current and the current value of the second current.

10. The semiconductor device according to claim 1,
wherein the current measurement circuit includes:
a first resistance element provided between a fourth external terminal to which a reference voltage of the battery is supplied and a low-potential-side terminal of a power supply circuit configured to generate an operating voltage of an internal circuit of the semiconductor device; and
an AD converter configured to detect a potential difference between both ends of the first resistance element, and
wherein a current value in accordance with a result of detection made by the AD converter is used as a result of measurement made by the current measurement circuit indicating the current value of the first current.

11. The semiconductor device according to claim 1,
wherein the current measurement circuit includes:
a plurality of first resistance elements provided between a first external terminal to which an output voltage of the battery is supplied and a high-potential-side terminal of each of a plurality of functional blocks provided to the semiconductor device; and
a plurality of AD converters each configured to detect a potential difference between both ends of each of the plurality of the first resistance elements, and
wherein a current value in accordance with a result of detection made by each of the plurality of AD converters is used as a result of measurement made by the current measurement circuit indicating the current value of the first current.

12. The semiconductor device according to claim 1,
wherein the current measurement circuit includes:
a plurality of first resistance elements provided between a first external terminal to which an output voltage of the battery is supplied and a high-potential-side terminal of each of a plurality of functional blocks provided to the semiconductor device;
a selector configured to selectively output any potential difference between both ends of each of the plurality of first resistance elements; and
an AD converter configured to detect the potential difference selected by the selector, and
wherein a current value in accordance with the potential difference between both ends of each of the plurality of first resistance elements detected by the AD converter is used as a result of measurement made by the current measurement circuit indicating the current value of the first current.

13. The semiconductor device according to claim 3, further comprising:
a comparator circuit configured to compare potentials at both ends of the first resistance element; and
a protection circuit configured to protect the semiconductor device from at least either overvoltage or overcurrent supplied from the battery when a result of comparison indicating that a potential difference between both ends of the first resistance element is equal to or larger than a threshold value is output from the comparator circuit.

14. A battery pack comprising:
the semiconductor device according to claims 1; and
the battery.

15. A method of controlling a semiconductor device comprising steps of:
measuring a current value of a first current supplied from a battery to the semiconductor device that is a host device and a current value of a second current supplied from the battery to a load; and
calculating a remaining capacity of the battery, based on an accumulation value of the first current and an accumulation value of the second current in a period from start of discharging to end of discharging in the battery.

16. A control program for causing a computer to perform:
a process of measuring a current value of a first current supplied from a battery to a semiconductor device that is a host device and a current value of a second current supplied from the battery to a load; and
a process of calculating a remaining capacity of the battery, based on an accumulation value of the first current and an accumulation value of the second current in a period from start of discharging to end of discharging by the battery.
